(19) United States
(12) Patent Application Publication
(10) Pub. No.: US 2006/0181848 A1
(43) Pub. Date: Aug. 17, 2006

(54) Heat sink and heat sink assembly

(76) Inventors: Richard F. Kiley, Holiday, FL (US); Simone Bush, Pinellas Park, FL (US)

Correspondence Address: Michael J. Persson;Lawson & Persson, P.C., Suite 103, 67 Water Street, Laconia, NH, 03246, US

(21) Appl. No.: 11/312,622

(22) Filed: Dec. 20, 2005

Related U.S. Application Data
(60) Provisional application No. 60/652,997, filed on Feb. 14, 2005.

(51) Int. Cl. H05K 7/20

(52) U.S. Cl. 361/697; 361/709

(57) ABSTRACT

A heat sink and a heat sink assembly that includes the heat sink and a source of flowing air, such as a fan. The heat sink includes a base from which a first plurality of convective surfaces extends. At least one heat pipe is in thermal contact with the base and extends therefrom. The heat pipe includes an evaporator portion in thermal contact with the base and a condenser portion. A second plurality of convective surfaces is in thermal communication with the condenser portion of the heat pipe.

### CLAIM OF PRIORITY

This patent application claims the benefit of priority of U.S. Provisional Patent Application Ser. No. 60/652,997, filed on Feb. 14, 2005.

### FIELD OF THE INVENTION

The present invention relates to the field of thermal management devices and, in particular, to heat sinks for convectively cooling electrical devices and components, and to assemblies utilizing these heat sinks.

### BACKGROUND OF THE INVENTION

Semiconductors and other electrical components generate heat as a by-product of their operation. As technology has advanced, the amount of heat to be dissipated from many of these components has risen dramatically, while the acceptable cost of heat dissipating devices has remained constant or, in many cases, has dropped. Consequently, the art of heat sinking to cool heat-dissipating components has continually evolved to meet these new market requirements.

Forced air convective heat sink assemblies are common in the industry and are preferred due to the large amount of heat that they can be dissipate and because they eliminate the risk of shorting inherent in liquid cooled heat sinks. Forced air convective heat sink assemblies have typically used finned metal heat sinks to dissipate heat generated by electrical components. These finned metal heat sinks generally include a substantially rectangular base plate to which the heat generating device or devices are mounted, and a plurality of fins projecting from the base plate for dissipating the generated heat. In many applications, a fan is attached to the assembly in order to force cooling air across the fins of the heat sink and enhance cooling from the heat sinks. In these applications, the amount of heat that may be dissipated from heat sink of given volume at a given air velocity is directly related to the efficiency of the heat sink.

Heat sink efficiency is defined as thermal performance generated per given volume. An efficient heat sink provides substantial cooling, while consuming a small physical volume. In general, the more surface area the heat sink has, the more heat you can typically transfer from the component. However, in many applications, other factors come into play that can limit the effectiveness of any increase in heat sink surface area. One common limiting factor is the amount of heat that may be conducted through the fins themselves.

Conduction losses occur because solid materials are not perfect conductors of heat. Therefore, in a conventional finned heat sink utilizing a base plate in thermal communication with a heat source, the temperature of the fin at a location proximate to the base is higher than that of fin at a location proximate to the fin tip. In heat sinks utilizing relatively short fins, the temperature difference between the base and tip portions of the heat sink are not usually significant. However, in heats sinks utilizing relatively long fins, the temperature at the tip of the fin can approach that of the ambient air. As the amount of heat transferred from a forced convection heat sink is directly related to the difference in temperature between the heat sink and ambient air (ΔT), little of no heat is transferred from the surface area proximate to the tips. This causes a significant reduction in the efficiency of the heat sink and effectively eliminates any advantage to adding surface area by lengthening fins.

Therefore, there is a need for a heat sink that overcomes the limitations caused by conduction losses through fins in order to efficiently cool heat-generating equipment.

### SUMMARY OF THE INVENTION

The present invention is a heat sink and a heat sink assembly that includes the heat sink and a source of flowing air, such as a fan. In its most basic form, the heat sink of the present invention includes a base from which a first plurality of convective surfaces extends. At least one heat pipe is in thermal contact with the base and extends therefrom. The heat pipe includes a conduction portion in thermal contact with the base and a convection portion. A second plurality of convective surfaces is in thermal communication with the convection portion of the heat pipe(s). In operation, a heat source is placed in thermal communication with the base, causing the temperature of the base to increase. Heat from the base is conducted directly into the first plurality of convective surfaces, causing their temperature to increase. Simultaneously, heat is conducted into the heat pipe causing the working fluid within to the heat pipe to change phase and travel to the convection portion, where it condenses and releases its heat for conduction into the second plurality of convective surfaces.

By utilizing the heat pipes as a second heat source for conduction into the second plurality of convective surfaces, the length of the conduction path from each heat source to the tips of the first and second pluralities of convective surfaces is shortened. This shortening of the conduction path reduces the conduction losses from what could be achieved by lengthening the first plurality of convective surfaces and results in a heat sink that is far more efficiently than would be possible in a heat sink having the same amount of surface area in which conduction occurred only through the base.

A heat pipe is a simple heat-exchange device that relies upon the boiling and condensation of a working fluid in order to transfer heat from one place to another. The basic principle behind all heat pipes is that a liquid must absorb a higher amount of heat in order to change it to a gas than to raise its temperature the same amount without changing phase. The amount of heat required to effect this phase change in a given fluid is referred to as the “latent heat of vaporization”. Similarly, because the second law of thermodynamics states that energy may not be lost, but may only be transferred from one medium to another, the energy that is absorbed by the fluid during its change to a gas is subsequently released when the gas is condensed back into a liquid. Because the latent heat of vaporization is usually very high, and the vapor pressure drop between the portion of the heat pipe in which the fluid is boiled and the portion where is it condensed is very low, it is possible to transport high amounts of heat from one place to another with a very small temperature difference from the heat source to the location of condensation. In fact, at a given temperature difference, a heat pipe is capable of conducting up to one hundred and fifty times as much heat as a solid copper pipe of equal cross section, and as much as three hundred times as much heat as an aluminum member of equal cross section. Therefore, heat pipes have traditionally been used to efficiently transfer heat from one point to another in applications where there is limited physical space to effect such cooling proximate to the heat source.

The present invention uses heat pipes in a manner in which they have not heretofore been utilized; i.e. in order to overcome conduction losses through finned heat sinks. As noted above, the basic embodiment of the heat sink of the present invention includes a base and a at least one heat pipe that extends from the base. The base is dimensioned and shaped to promote good thermal contact with the heat source, and the heat pipes are attached thereto in such a manner as to promote good thermal contact to the working fluid. Each heat pipe includes an outer surface and an inner surface that form a condenser portion from which from heat is transferred during condensation of the working fluid. In some embodiments, each heat pipe is a closed system that includes its own working fluid and an evaporator portion that is in contact with the heat sink base or a conductor block mounted in thermal contact with the base. However, in other embodiments the heat pipes share a common reservoir of working fluid, preferably located within the base plate, and do not include individual evaporator portions.

It is preferred that the evaporator portions of the heat pipes are mounted in close proximity the mounting surface to reduce conduction losses through the base. By mounting the heat pipes in this arrangement, the amount of heat transferred into the heat pipes is maximized. This feature is unique to the present invention and is believed to be of significant advantage over current designs. However, as described below, the heat pipes are mounted proximate to interface between the first plurality of convective surfaces in other embodiments to achieve acceptable results.

The type, number, and layout of the heat pipes extending from the base are largely a function of the application in which the heat sink is to be used. Further, the configuration of the heat pipe(s) may be varied in order to dispose the second plurality of convective surfaces proximate to the first plurality of convective surfaces such that the combination appears as a single conventional heat sink, or it may be configured to move the second plurality of convective surfaces to a location remote from the first plurality of convective surfaces.

In some embodiments of the invention, the heat pipes are merely pressure vessels having a working fluid disposed therein that simply exploits gravitational forces to return condensed fluid flow to the evaporator portion thereof. In these embodiments, the heat sink assembly is dimensioned for mounting such that, in operation, the heat source is at a lower elevation than the condenser portions of the heat pipes. In other embodiments, however, the heat pipes utilize wicks or other fluid transport means for transporting the condensed fluid to their evaporator portions. In these embodiments, the relationship between the assembly and the heat source is irrelevant, allowing the heat sink to be mounted in a variety of orientations.

The first plurality of convective surfaces is preferably a plurality of substantially planar fins that extend from the base plate. These fins may be extruded along with the base, cast along with the base, or attached to the base via epoxy, solder, brazing, or other art recognized means. Although the preferred first plurality of convective surfaces are fins, it is likewise recognized that these surfaces may be pins, pieces of formed sheet metal, such as convoluted fins, honeycomb fins, radiator-type fins, or any other art recognized means for convecting heat from a surface. Similarly, the second plurality of convective surfaces is preferably a plurality of substantially planar fins that extend from the convective portion of the heat pipe, but may also be pins, pieces of formed sheet metal, such as convoluted fins, honeycomb fins, radiator-type fins, or any other art recognized means for convecting heat from a surface.

Regardless of what form the first plurality of convective surfaces and the second plurality of convective surfaces take, it is preferred that the be dimensioned such that the surfaces are substantially optimized; i.e. the temperature difference between the tip of the surface and the base of the surface is not so great as to substantially reduce the efficiency of the heat sink.

The basic embodiment of the heat sink assembly of the present invention includes the basic embodiment of the heat sink discussed above and a means for forcing air over at least one of the first and second pluralities of heat convecting surfaces. The means for forcing air over the heat convecting surfaces is preferably a fan or blower that is mounted directly to the heat sink in a desired orientation. In some embodiments, the fan is mounted to the heat sink by attaching a pair of side plates to the outside edges of the base plate and attaching a fan to these side plates. The fan may be mounted to the side plates such that air flows in a direction parallel to the plane formed by the base plate or such that air flows perpendicular to, and impinges upon, the base plate.

In some embodiments of the assembly, the heat source is an integral part thereof. Accordingly, the present invention contemplates heat sink assemblies in which components are mounted to the base plate, or the base plate forms part of the heat generating device or component itself. For example, the base plate could form an integral part of the housing of a power supply, be laminated to a printed circuit board, or otherwise integrated with the heat source itself.

Therefore, it is an aspect of the present invention to provide a heat sink that uses air convection to cool heat generating devices, such electrical devices and components, fuel cells, or other sources of heat to which heat sinks and heat sink assemblies are commonly attached.

It is a further aspect of the present invention to provide a highly efficient heat sink that minimizes conduction losses, and hence temperature differences, between the areas of the convective surfaces proximate to the base and those proximate to their tips.

It is a still further aspect of the present invention to provide a heat sink that is capable of distributing high heat loads.

It is a still further aspect of the present invention to provide a heat sink that allowing a matching of heat sources and heat sinks with differing thermal characteristics.

It is a still further aspect of the present invention to provide a heat sink capable of reducing overall system size and costs from those currently available.

It is a still further aspect of the present invention to provide a heat sink assembly that does not require active liquid cooling to dissipate large amounts of power from a heat generating component or device.

It is a still further aspect of the present invention to provide a heat sink assembly that may be used in forced air convection cooling systems.

It is a still further aspect of the present invention to provide a heat sink in which heat pipes are mounted proximate to the mounting surface in order to maximize heat flow from the heat source to the second plurality of convective surfaces.

These aspects of the invention are not meant to be exclusive and other features, aspects, and advantages of the present invention will be readily apparent to those of ordinary skill in the art when read in conjunction with the following description, and accompanying drawings.

### BRIEF DESCRIPTION OF THE DRAWINGS

FIG. 1A is an exploded assembly view of the preferred embodiment of the heat sink assembly of the present invention.

FIG. 1B is a side view of the heat sink assembly of FIG. 1A.

FIG. 1C is an end view of the heat sink assembly of FIG. 1A.

FIG. 2 is as cut away side view of one embodiment of a heat pipe demonstrating its use.

FIG. 3 is an isometric view of an alternative embodiment of the heat sink of the present invention.

FIG. 4 is an isometric view of another alternative embodiment of the heat sink of the present invention.

FIG. 5A is an isometric view of an alternative embodiment of the heat sink assembly of the present invention.

FIG. 5B is an exploded view of the base plate of the embodiment of FIG. 5A showing the conductor plate heat pipe and join between the first plurality of fins and the base plate.

FIG. 6 is an isometric view of another alternative embodiment of the heat sink assembly of the present invention.

FIG. 7 is an isometric view of another alternative embodiment of the heat sink assembly of the present invention in which the first plurality of convective surfaces are pin fins.

FIG. 8 is an isometric view of still another alternative embodiment of the heat sink assembly of the present invention in which the second plurality of convective surfaces are round fins that are attached to heat pipes that extend vertically from a common conductor plate.

### DETAILED DESCRIPTION OF THE INVENTION

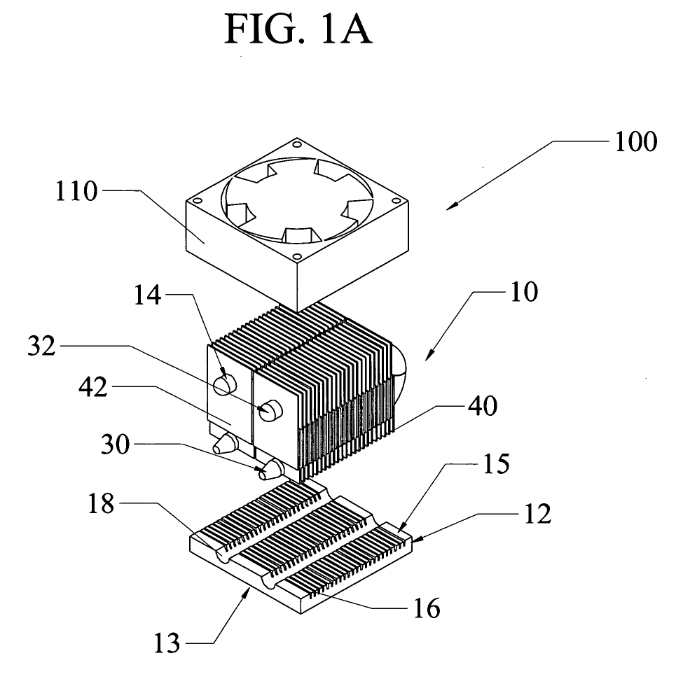

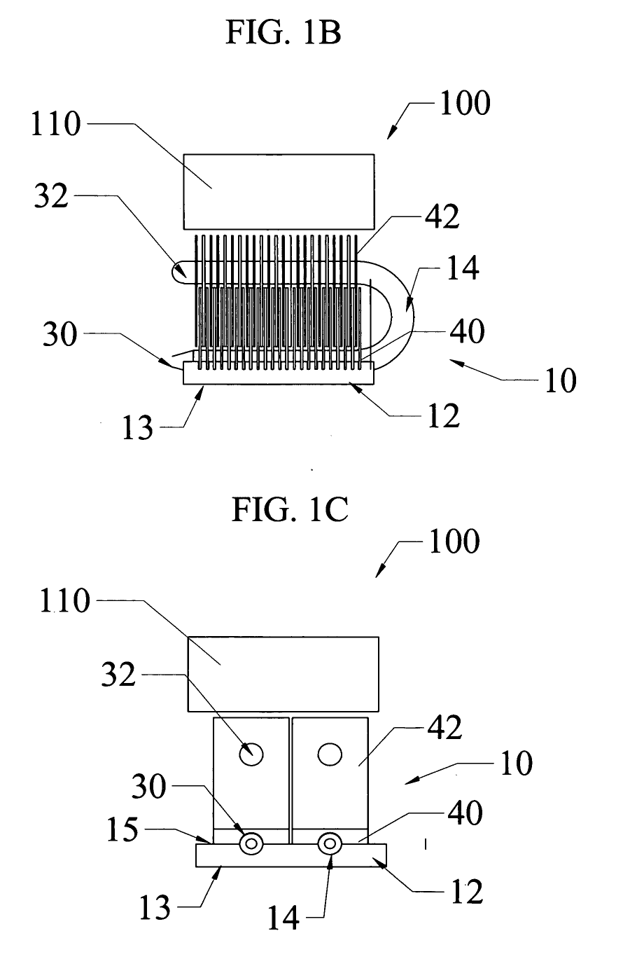

Referring first to FIGS. 1A-1C, one embodiment of the heat sink assembly 100 of the present invention is shown. The heat sink assembly 100 includes a heat sink 10 and a fan 110. The heat sink includes a base plate 12, a first plurality of convective surfaces, shown here as fins 40, a pair of heat pipes 14, and a second plurality of convective surfaces 42, shown here as fins 42.

The top surface 15 of the base plate 12 includes a plurality of slots 16, into which the first plurality of fins 40, are attached, and a pair of channels 18, into which the evaporator portions 30 of a pair of heat pipes 14 are attached. The base plate 12 has a bottom surface 13 that is dimensioned and shaped to promote good thermal contact with the heat source (not shown). The base plate 12 is manufactured of a material, such as copper or aluminum, that has relatively good thermal conductivity, and should be of sufficient thickness to efficiently spread the heat from a heat source (not shown) disposed upon its bottom surface 13 to the first plurality of fins 40 and the heat pipes 14 attached to its top surface 15. In many of the embodiments shown herein, the base plate 12 is portrayed as a substantially solid rectangular plate. However, it is recognized that base plates 12 having different shapes and/or cross sections may be utilized and the present invention should not be viewed as being limited to heat sinks 10 having rectangular base plates 12.

The second plurality of fins 42 are attached in heat conducting relation with the outer surface 22 of the condenser portion 32 of the heat pipe 14. Each of the second plurality of fins 42 is preferably manufactured of a conductive material, such as copper or aluminum, and is affixed to the outer surface 22 of the heat pipe 14 in such a manner as to promote good heat flow therefrom such that the fins 42 can be said to form an integral part of each heat pipe 14. This may be accomplished through a number of art-recognized processes, including brazing, soldering, epoxy bonding, press fitting, mechanical or other means. As explained below, the fins 42 are spaced apart from one another a distance that is determined by the nature of the airflow between these spaces and the relationship between these fins 42 and the first plurality of fins 40 extending from the base plate 12.

In the embodiment of FIGS. 1A-1C, it is preferred that the first plurality of fins 40 be aligned with the second plurality of fins 42 such a portion of each of the second plurality of fins 42 occupies a portion of the channel formed between adjacent fins 40. This arrangement is preferred in this embodiment as the air generated by the fan 110 is directed to impinge upon the top surface 15 of the base plate 12, which reduces the amount of boundary layer choking that may occur were the fan 110 oriented for parallel flow over the base plate 12. Therefore, this “nesting” of fins 40, 42 allows the overall volume of the heat sink 10 to be reduced without significant loss in thermal performance, resulting in a more efficient heat sink than could otherwise be obtained. However, as discussed in detail below, this arrangement of fins 40, 42 is not preferred in other embodiments.

The heat pipes 14 of the heat sink 10 of FIGS. 1A-1C are substantially “U” shaped, such that the evaporator portion 30 and condenser portion 32 are substantially parallel to each other. In this arrangement, each of the first plurality of fins 40 includes notches that correspond to the location of the evaporator portion 30 of one of the heat pipes 14 and each of the second plurality of fins 42 includes an opening therethrough that is dimensioned to align and mate with the condenser portion 30 of one of the heat pipes 14. However, as described in detail below, the inventors recognize that the relation between the heat pipes 14, first plurality of fins 40 and second plurality of fins 42 are largely dependent upon the application in which the heat sink 10 is to be used and that the embodiments described herein are merely those that are currently preferred.

The evaporator portions 30 of each heat pipe 14 may be affixed to the base plate 12 in a number of ways. As shown in FIGS. 1A-1C, this is accomplished by forming mating grooves 18 in the top surface 15 of the base plate 12, disposing the evaporator portion 30 of the each heat pipe 14, and securing the heat pipes 14 into the grooves 18 via press fitting. However, in other such embodiments, the evaporator portions 30 of the heat pipes 14 are affixed by soldering, brazing, epoxy bonding, mechanical fasteners, such as a bar and screws, or other art-recognized means for securing an elongate object into a flat plate.

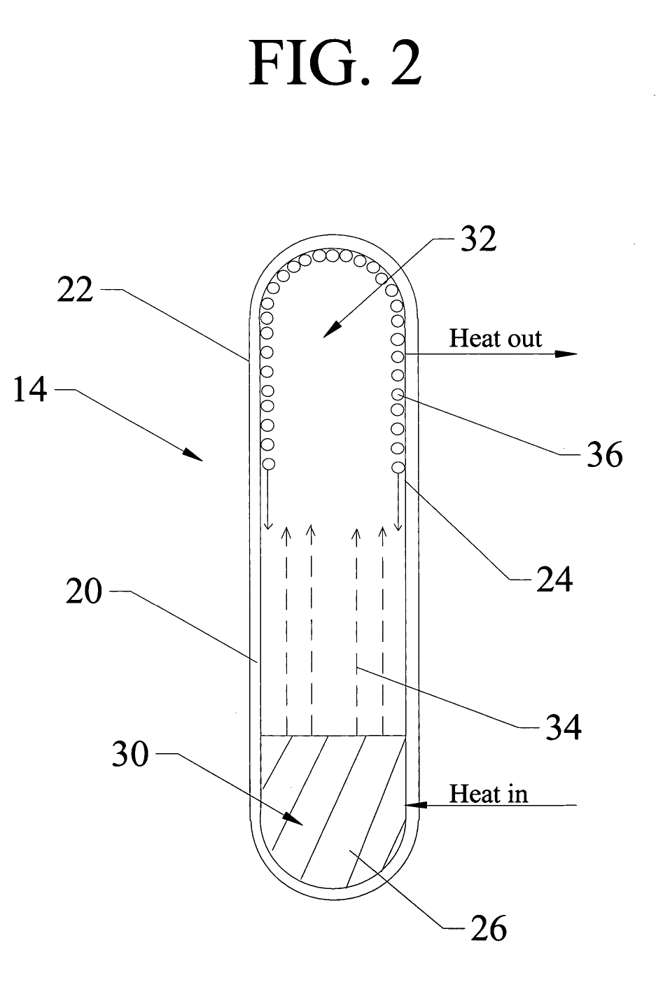

The heat pipes 14 may take many forms, and virtually any type of heat pipes 14 currently available could be joined to the top surface 15 of the base plate 12. As shown in FIG. 2, one type of heat pipe 14 that could be used includes a closed pressure vessel 20 having an outer surface 22 and an inner surface 24, and in which a working fluid, in the form of a liquid 26, is disposed. The liquid 26 is disposed in the evaporator portion 30 of the vessel, where it is heated and changes phase into a gaseous working fluid 34. The gaseous working fluid 34 then fills the remaining interior of the vessel 20, which forms the condenser portion 32 thereof. Because the outer surface 22 of the vessel 20 surrounding the condenser portion 32 is cooler then the interior of the vessel 20, heat flows from the inner surface 24 to the outer surface 22, where is it convectively removed from the system. This transfer of this heat is accomplished through condensation of the gaseous working fluid 34, which releases the latent heat of vaporization from the fluid 34 and forms droplets of condensate 36 along the inner surface 24 of the vessel 20. The condensate 36 is then transported by gravitational forces back into the evaporator portion 30 of the vessel 20 and mixes with the liquid 26, where the cycle is repeated.

As demonstrated by the above description, the vessel 20 isolates the working fluid 26, 34, 36 from the outside environment. By necessity, the vessel 20 must be leak-proof, maintain the pressure differential across its walls, and enable transfer of heat to take place from and into the working fluid. Selection of a fabrication material for the vessel 20 depends on many factors including chemical compatibility, strength-to-weight ratio, thermal conductivity; ease of fabrication, porosity, etc. Once filled with the working fluid 26, the vessel 20 is preferably evacuated to eliminate any pockets of air that might otherwise prevent the flow of the gaseous working fluid 34 to substantially the entire inner surface 24 of the condenser portion 32 of the vessel 20.

Working fluids 26 are many and varied. The prime consideration is the selection of the working fluid 26 is operating vapor temperature range. Often, several possible working fluids 26 may exist within the approximate temperature band. Various characteristics must be examined in order to determine the most acceptable of these fluids for the application considered such as good thermal stability, compatibility with wick and wall materials, vapor pressure relative to the operating temperature range, high latent heat, high thermal conductivity, liquid phase viscosities and surface tension, and acceptable freezing or pour point, to name a few. The selection of the working fluid 26 must also be based on thermodynamic considerations, which are concerned with the various limitations to heat flow occurring within the heat pipe like, viscous, sonic, capillary, entrainment and nucleate boiling levels. Many conventional heat pipes use water and methanol as working fluid, although other more exotic materials, such as fluorocarbons, are also used.

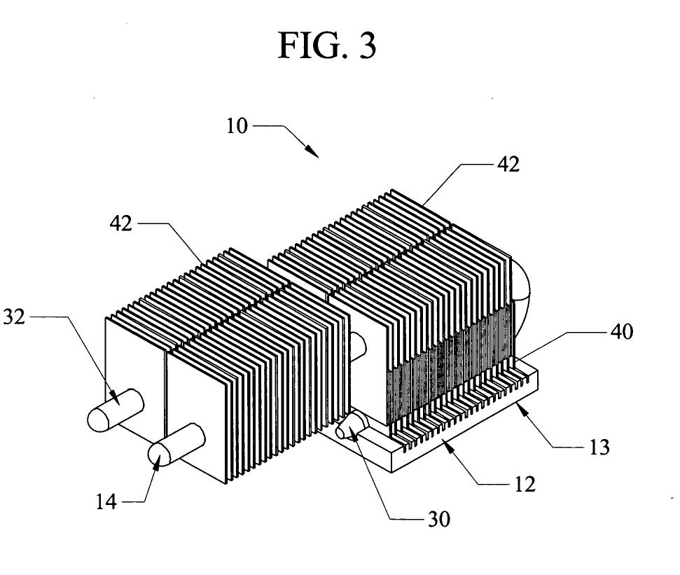

The heat pipe 14 described in connection with FIG. 2 is a basic design that requires the heat sink 10 to be orientated such that gravity will cause the evaporated fluid to rise to the condenser portion 32 and return the condensate 36 to the evaporator portion 30 after is has evaporated. However, other embodiments of the invention, such as those shown in FIGS. 1A-1C and FIG. 3, utilize heat pipes 14 having internal wicks (not shown), or other fluid transport means for transporting the condensate 36 to their evaporator portions 30. A typical wick is a porous structure, made of materials like steel, aluminum, nickel or copper in various pore size ranges. Wicks are typically fabricated using metal foams, and more particularly felts, with the latter being more frequently used. By varying the pressure on the felt during assembly, various pore sizes can be produced. By incorporating removable metal mandrels, an arterial structure can also be molded in the felt. The prime purpose of the wick is to generate capillary pressure to transport the condensate 36 from the condenser portion 32 of the vessel to the evaporator portion 30 proximate to the heat source (not shown). It must also be able to distribute the liquid 26 around the evaporator portion 30 to any area where heat is likely to be received by the heat pipe 14. Often these two functions require wicks of different forms. The selection of the wick for a heat pipe depends on many factors, several of which are closely linked to the properties of the working fluid. However, such selection is an art unto itself and, therefore, is not discussed herein.

Finally, it is noted that, the heat pipe 14 of FIG. 2 is shown as a substantially straight tubular pressure vessel for purposes of clarity. However, it is recognized that heat pipes 14 taking the forms of those shown in other figures and described in the description herein, or other art recognized forms, will follow the same principles. Therefore, the invention should not be seen as being limited to the particular type and shape of that shown and described with reference to FIG. 2.

Referring now to FIG. 3, an alternative embodiment of the heat sink 10 is shown. This embodiment is substantially identical to the embodiment of FIGS. 1A-1C, except that the condenser portion 32 of the heat pipes 14 are extended beyond the periphery of the base plate 12 and substantially more fins 42 make up the second plurality of fins than make up the first plurality of fins 40.

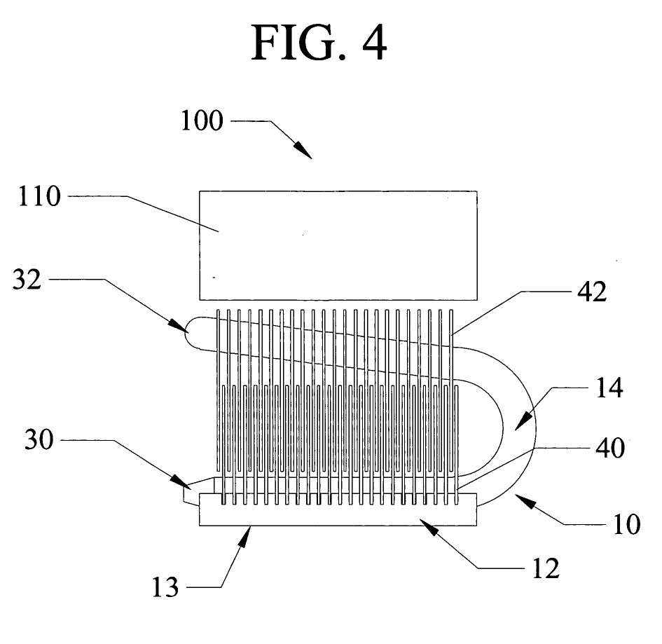

Referring now to FIG. 4, another embodiment of the heat sink assembly 100 is shown. The heat sink assembly 100 of this embodiment is similar in all respects to the embodiment of FIGS. 1A-1C, except that the heat pipes 14 are not substantially “U” shaped, but rather includes a condenser portion 32 that extend slightly upward at an angle. By utilizing a heat pipe 14 having an angled condenser portion 32, a wickless heat pipe 14, similar to that shown in FIG. 2, may be utilized.

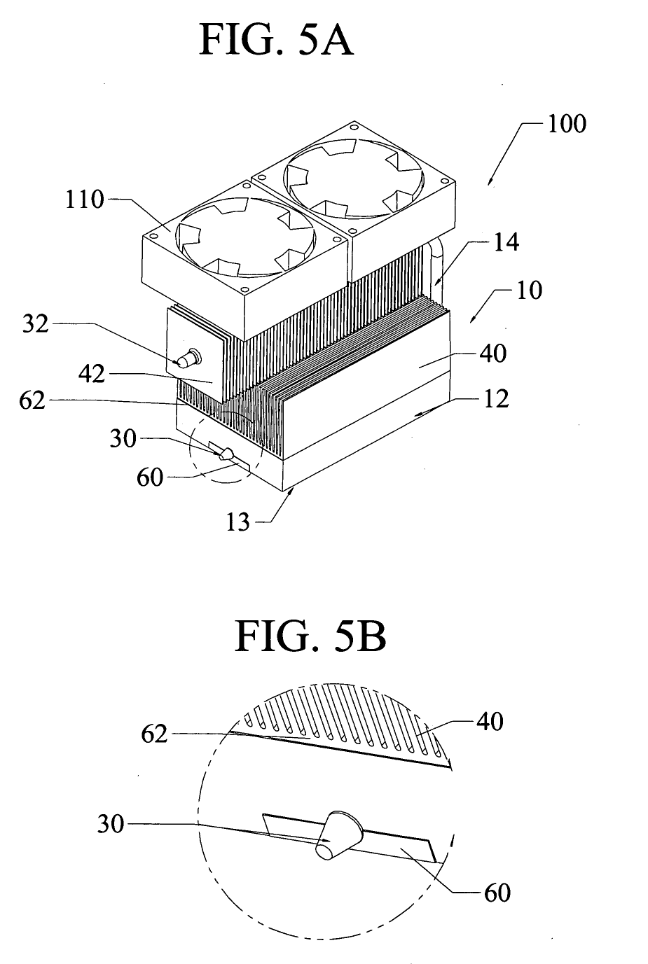

Referring now to FIGS. 5A and 5B, another embodiment of the heat sink assembly 100 is shown. In this embodiment, the base plate 12 of the heat sink 10 does not include slots 16, but rather has the first plurality of fins 40 formed integral thereto. This is preferably accomplished by forming the fins 40 together with the base plate 12 through extrusion, casting, or other art recognized methods for forming conventional heat sinks.

In the embodiment of FIGS. 5A and 5B, the channel 18 within the base plate 12 is moved from the top surface 15 to the bottom surface 13 and is dimensioned to mate with a conductor plate 60 into which the evaporator portion 30 of the heat pipe 14 is disposed. In this embodiment, the conductor plate 60 is preferably a substantially solid plate of a thermally conductive material, such as copper. However, in other embodiments, the conductor plate 60 is substantially hollow and forms a part of the evaporator portion 30 of the heat pipe 14.

The embodiment of FIGS. 5A and 5B includes a single heat pipe 14 that is substantially “U” shaped and extends over the tips of the first plurality of fins 40 in a manner similar to that of FIGS. 1A-1C and FIG. 3. However, this is shown for illustrative purposes and two or more heat pipes 14 may be preferred in embodiments having wider base plates 12.

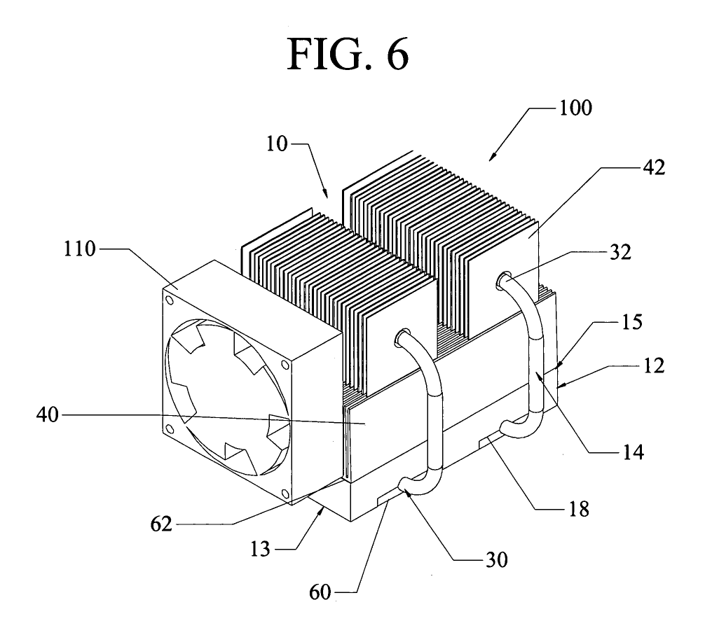

Finally, in this embodiments, the second plurality of fins 42 are not nested within the spaces between the fins 40, but rather are oriented above and in perpendicular relation to the first plurality of fins 40. The embodiment of FIGS. 6A and 6B utilizes two fans 110, although one fan 110, or more than two fans 110 could be used to achieve similar results.

Referring now to FIG. 6, another embodiment of the heat sink assembly 100 is shown. This embodiment utilizes a similar arrangement as the embodiment of FIGS. 5A and 5B insofar as the first plurality of convective surfaces 40 are formed integral to the base 12, and insofar as the channel 18 is disposed upon the bottom surface 13 and is dimensioned to mate with the conductor plate 60 into which the heat pipe 14 is disposed. However, the embodiment of FIG. 6 utilizes two conductor plates 60 and heat pipes 14, the second plurality of fins 42 are in parallel relation to the first plurality of fins 40 and the fan 110 is disposed to create a flow of air that is parallel, rather than perpendicular, to the base plate 12.

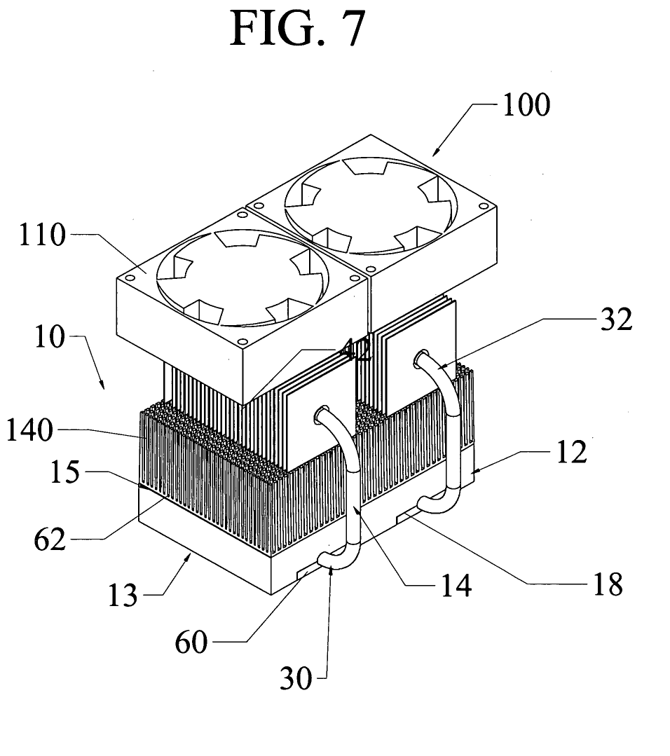

Referring now to FIG. 7, still another embodiment of the heat sink assembly 100 is shown. This embodiment utilizes a similar arrangement as the embodiment of FIGS. 5A, 5B and 7 insofar as the first plurality of convective surfaces 40 are formed integral to the base 12, and insofar as the channel 18 is disposed upon the bottom surface 13 and is dimensioned to mate with the conductor plate 60 into which the heat pipe 14 is disposed. However, in the embodiment of FIG. 7 the first plurality of convective surfaces are pin fins 140 rather than the substantially planar fins 40 shown in other embodiments.

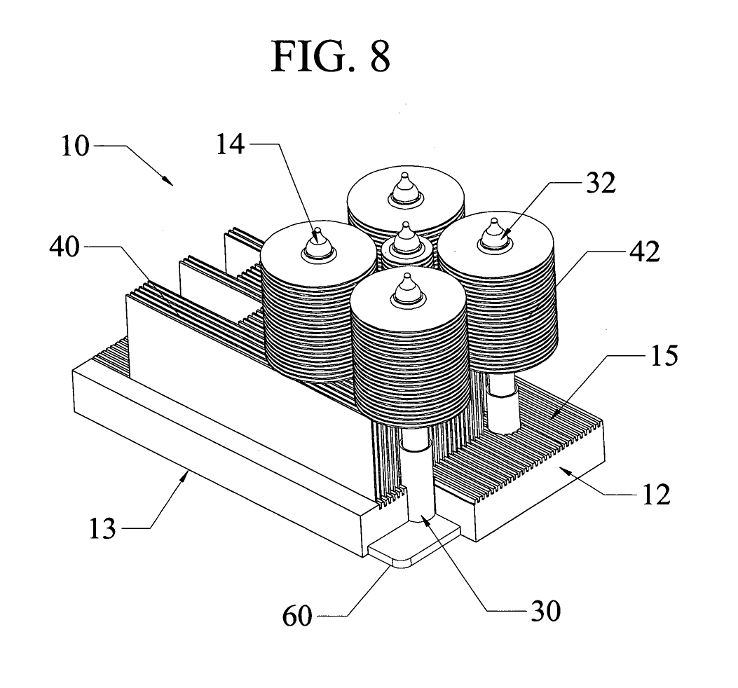

Referring now to FIG. 8 still another embodiment of the heat sink assembly 100 is shown. This embodiment utilizes a conductor plate 60 from which a plurality of heat pipes 14 extend. All heat pipes 14 extend substantially vertically from the common conductor plate 60 and attach thereto such that the evaporator portion 30 of each heat pipe 14 is in thermal conduction with the conductor plate. The second plurality of convective surfaces in this embodiment is made up of round fins 42 that are attached to, and extend axially from, the condenser portions 32 of each heat pipe. As the embodiment of FIG. 8 demonstrates, the second plurality of convective surfaces need not each be attached to the same heat pipe 14, nor do they need to be of the same cross section, or extend in the same plane as the first plurality of convective surfaces.

Although the present invention has been described in considerable detail with reference to certain preferred versions thereof, other versions would be readily apparent to those of ordinary skill in the art. Therefore, the spirit and scope of the appended claims should not be limited to the description of the preferred versions contained herein.

What is claimed is:

1. A heat sink for dissipating heat from a heat source, said heat sink comprising:
a heat-conductive base comprising a top surface and a bottom surface;
a first plurality of convective surfaces in heat conducting relation to at least said top surface of said heat-conductive base;
at least one heat pipe in heat conducting relation to and extending from said heat-conductive base, wherein said at least one heat pipe comprises an inner surface, and outer surface and a working fluid disposed in contact with said inner surface, wherein said at least one heat pipe comprises an evaporator portion and a condenser portion, and wherein said evaporator portion of said heat pipe is disposed in heat conductive relation to said heat-conductive base in such a manner as to promote good thermal contact between said base and said working fluid disposed within said at least one heat pipe; and
a second plurality of convective surfaces in heat conducting relation to said condenser portion of said heat pipe;
wherein at least a portion of said second plurality of convective surfaces is disposed in proximate relation to said first plurality of convective surfaces such that air passing over said first plurality of convective surfaces will also pass over said second plurality of convective surfaces.

2. The heat sink as claimed in claim 1:
wherein first plurality of convective surfaces comprise a plurality of substantially planar fins defining a plurality of channels:
wherein said second plurality of convective surfaces comprise a plurality of substantially planar fins; and
wherein at least a portion of said second plurality of substantially planar fins is disposed within said plurality of channels defined by said first plurality of substantially planar fins.

3. The heat sink as claimed in claim 1 wherein said at least one heat pipe comprises at least one substantially U-shaped heat pipe.

4. The heat sink as claimed in claim 3 wherein said condenser portion of said at least one substantially U-shaped heat pipe extends beyond a periphery of said base plate.

5. The heat sink as claimed in claim 3 further comprising at least one conductor plate attached to said bottom surface of said base, wherein said evaporator portion of at least one heat pipe is disposed within at least one conductor plate.

6. The heat sink as claimed in claim 1 further comprising at least one conductor plate attached to said bottom surface of said base, wherein said evaporator portion of at least one heat pipe is disposed within at least one conductor plate.

7. The heat sink as claimed in claim 6 wherein at least one heat pipe extends from said conductor plate in substantially perpendicular relation to said base and wherein said second plurality of convective surfaces comprises a plurality of substantially planar fins disposed in substantially parallel relation to said base.

8. The heat sink as claimed in claim 1 wherein said first plurality of convective surfaces in heat conducting relation to said heat-conductive base comprise a plurality of substantially planar fins attached to said heat-conductive base.

9. The heat sink as claimed in claim 1 wherein said first plurality of convective surfaces in heat conducting relation to said heat-conductive base comprise a plurality of substantially planar fins formed integral to said heat-conductive base.

10. A heat sink assembly comprising:
at least one fan for creating a flow of air; and
a heat sink disposed within a path of said flow of air created by said fan, said heat sink comprising:
a heat-conductive base;
a first plurality of convective surfaces in heat conducting relation to said heat-conductive base;
at least one heat pipe in heat conducting relation to and extending from said heat-conductive base, wherein said at least one heat pipe comprises an inner surface, and outer surface and a working fluid disposed in contact with said inner surface, wherein said at least one heat pipe comprises an evaporator portion and a condenser portion, and wherein said evaporator portion of said heat pipe is disposed in heat conductive relation to said heat-conductive base in such a manner as to promote good thermal contact between said base and said working fluid disposed within said at least one heat pipe; and
a second plurality of convective surfaces in heat conducting relation to said condenser portion of said heat pipe;
wherein said second plurality of convective surfaces is disposed in proximate relation to said first plurality of convective surfaces such that said flow of air from said fan passes over said first plurality of convective surfaces and said second plurality of convective surfaces.

11. The heat sink assembly as claimed in claim 10 wherein at least one fan is attached to said heat sink.

12. The heat sink assembly as claimed in claim 10:
wherein first plurality of convective surfaces comprise a plurality of substantially planar fins defining a plurality of channels:
wherein said second plurality of convective surfaces comprise a plurality of substantially planar fins; and
wherein at least a portion of said second plurality of substantially planar fins is disposed within said plurality of channels defined by said first plurality of substantially planar fins.

13. The heat sink assembly as claimed in claim 10 wherein said at least one heat pipe comprises at least one substantially U-shaped heat pipe.

14. The heat sink assembly as claimed in claim 13 wherein said condenser portion of said at least one substantially U-shaped heat pipe extends beyond a periphery of said base plate.

15. The heat sink assembly as claimed in claim 13 further comprising at least one conductor plate attached to said bottom surface of said base, wherein said evaporator portion of at least one heat pipe is disposed within at least one conductor plate.

16. The heat sink assembly as claimed in claim 10 further comprising at least one conductor plate attached to said bottom surface of said base, wherein said evaporator portion of at least one heat pipe is disposed within at least one conductor plate.

17. The heat sink assembly as claimed in claim 16 wherein at least one heat pipe extends from said conductor plate in substantially perpendicular relation to said base; wherein said second plurality of convective surfaces comprises a plurality of substantially planar fins disposed in substantially parallel relation to said base; and wherein at lest one fan is disposed so as to direct a flow of air through said fins in a direction parallel to said base.

18. The heat sink assembly as claimed in claim 10 wherein said second plurality of convective surfaces comprises a plurality of substantially planar fins disposed in substantially perpendicular relation to said base; and wherein at lest one fan is disposed so as to direct a flow of air through said fins in a direction substantially perpendicular to said base.

19. The heat sink assembly as claimed in claim 10 wherein said first plurality of convective surfaces in heat conducting relation to said heat-conductive base comprise a plurality of substantially planar fins attached to said heat-conductive base.

20. The heat sink assembly as claimed in claim 10 wherein said first plurality of convective surfaces in heat conducting relation to said heat-conductive base comprise a plurality of substantially planar fins formed integral to said heat-conductive base.
